(19) United States
(12) Patent Application Publication
(10) Pub. No.: US 2014/0008775 A1
(43) Pub. Date: Jan. 9, 2014

(54) SEMICONDUCTOR DEVICE

(71) Applicant: Elpida Memory, Inc., Tokyo (JP)

(72) Inventors: Sensho USAMI, Tokyo (JP); Koji HOSOKAWA, Tokyo (JP)

(21) Appl. No.: 13/933,318

(22) Filed: Jul. 2, 2013

(30) Foreign Application Priority Data
Jul. 4, 2012 (JP) 2012-150755

(51) Int. Cl. H01L 23/06

(52) U.S. Cl. CPC H01L 23/06
USPC 257/669

(57) ABSTRACT

A semiconductor device includes a wiring board, a semiconductor chip mounted over a surface of the wiring board, a sealing resin provided over the surface of the wiring board to cover the semiconductor chip, and a low-elasticity resin provided between the wiring board and the sealing resin. The low-elasticity resin is arranged outside of an area on which the semiconductor chip is mounted. The low-elasticity resin has an elastic modulus lower than an elastic modulus of the sealing resin.

This application is based upon and claims the benefit of priority from Japanese patent application No. 2012-150755, filed on Jul. 4, 2012, the disclosure of which is incorporated herein in its entirety by reference.

The disclosure of Japanese patent application No. 2011-259205, filed on Nov. 28, 2011, is incorporated herein in its entirety by reference.

### TECHNICAL FIELD

The present invention relates to a semiconductor device, and more particularly to a ball grid array (BGA) type semiconductor device.

### BACKGROUND

Generally, a ball grid array (BGA) type semiconductor device includes a wiring board, and a semiconductor chip mounted on the wiring board, and bonding wires electrically connecting electrode pads of the semiconductor chip to connection pads of the wiring board.

Examples of technology relating to this BGA type semiconductor device include JP-A 2011-54771 (Patent Literature 1). Patent Literature 1 discloses a BGA type semiconductor device having a wiring board, a semiconductor chip mounted on the wiring board, and a sealing resin formed on the wiring board so that the semiconductor chip is covered with the sealing resin. Patent Literature 1 also discloses a technique of reducing a warp of the semiconductor device by baking the semiconductor device while applying a load to the sealing resin after the sealing of the resin.

In the aforementioned BGA type semiconductor device, the wiring board, the semiconductor chip, and the sealing resin are made of different materials. Therefore, a warp is caused to the semiconductor device. By baking a semiconductor device while applying a load to a sealing resin after sealing of the resin as in Patent Literature 1, a warp of the semiconductor device can be reduced to some extent. However, if an excessive warp is caused to the semiconductor device, such a warp may not be reduced by baking with a load to a level that would cause no problem in packaging.

Accordingly, a warp of a semiconductor device should be adjusted at a development stage by changing materials of a wiring board or a sealing resin. Such adjustment of a warp of a semiconductor device requires repetitive trial products made by, for example, changes of materials of a wiring board or a sealing resin. Therefore, the development period is extended, resulting in an increased cost of semiconductor devices.

From this point of view, there has been developed technology of covering a semiconductor element with a low-elasticity resin to reduce a stress at a connection portion between a wiring board and the semiconductor element (semiconductor chip). See JP-A 2006-120935 (Patent Literature 2).

However, if a low-elasticity resin is disposed on a semiconductor chip as in Patent Literature 2, a sealing resin should also be provided on the low-elasticity resin because it is difficult to produce a mark on the low-elasticity resin. Therefore, the thickness of the sealing resin is increased on the semiconductor chip, thus preventing reduction in thickness of the semiconductor device.

### SUMMARY

In one embodiment, there is provided a semiconductor device, comprising:

a wiring board;

a semiconductor chip mounted over a surface of the wiring board;

a sealing resin provided over the surface of the wiring board to cover the semiconductor chip; and

a low-elasticity resin provided between the wiring board and the sealing resin, the low-elasticity resin being arranged outside of an area on which the semiconductor chip is mounted,

wherein the low-elasticity resin has an elastic modulus lower than an elastic modulus of the sealing resin.

In another embodiment, there is provided a semiconductor device comprising:

a substrate including an upper surface thereof;

a semiconductor chip including a first surface defined by first and second edges opposite to each other and by third and fourth edges opposite to each other and a plurality of electrode pads formed on the first surface along each of the first and second edges, and the semiconductor chip being mounted over the upper surface of the substrate;

a plurality of connection pads provided on the upper surface of the substrate, the connection pads being arranged along each of the first and second edges of the semiconductor chip, and the connection pads being electrically coupled to the electrode pads of the semiconductor chip, respectively;

first and second low-elasticity resins provided over the upper surface of the substrate, the first low-elasticity resin being arranged along the third edge of the semiconductor chip, and the second low-elasticity resin being arranged along the fourth edge of the semiconductor chip; and

a sealing resin provided over the upper surface of the substrate to cover the semiconductor chip and the first and second low-elasticity resins,

wherein an elastic modulus of the first and second low-elasticity resin is smaller than that of the sealing resin.

In the other embodiment, there is provided a semiconductor device comprising:

a substrate;

a semiconductor chip including a plurality of electrode pads thereon, and the first semiconductor chip being mounted over an upper surface of the substrate;

a plurality of connection pads formed on the upper surface of the substrate so as to arrange outside of the semiconductor chip, and the connection pads being coupled to the electrode pads of the semiconductor chip;

a low-elasticity resin provided over the upper surface of the substrate so as to surround the semiconductor chip in plan view; and

a sealing resin provided over the first surface of the substrate to cover the semiconductor chip and the low-elasticity resin,

wherein the low-elasticity resin has an elastic modulus lower than an elastic modulus of the sealing resin.

### BRIEF DESCRIPTION OF THE DRAWINGS

The above features and advantages of the present invention will be more apparent from the following description of certain preferred embodiments taken in conjunction with the accompanying drawings, in which

FIG. 1A is a plan view showing an outlined configuration of a semiconductor device according to a first embodiment of the present invention.

FIG. 1B is a diagram showing an outlined configuration of the semiconductor device according to the first embodiment of the present invention and is a cross-sectional view taken along line C-C′ of FIG. 1A.

FIG. 2A is a cross-sectional view showing a flow of assembling a semiconductor device according to the first embodiment of the present invention.

FIG. 2B is a cross-sectional view showing a flow of assembling the semiconductor device according to the first embodiment of the present invention.

FIG. 2C is a cross-sectional view showing a flow of assembling the semiconductor device according to the first embodiment of the present invention.

FIG. 2D is a cross-sectional view showing a flow of assembling the semiconductor device according to the first embodiment of the present invention.

FIG. 2E is a cross-sectional view showing a flow of assembling the semiconductor device according to the first embodiment of the present invention.

FIG. 3 is a cross-sectional view showing a variation of the semiconductor device according to the first embodiment of the present invention.

FIG. 4A is a plan view showing an outlined configuration of a semiconductor device according to a second embodiment of the present invention.

FIG. 4B is a diagram showing an outlined configuration of the semiconductor device according to the second embodiment of the present invention and is a cross-sectional view taken along line A-A′ of FIG. 4A.

FIG. 4C is a diagram showing an outlined configuration of the semiconductor device according to the second embodiment of the present invention and is a cross-sectional view taken along line B-B′ of FIG. 4A.

FIG. 5A is a plan view showing an outlined configuration of a semiconductor device according to a third embodiment of the present invention.

FIG. 5B is a diagram showing an outlined configuration of the semiconductor device according to the third embodiment of the present invention and is a cross-sectional view taken along line D-D′ of FIG. 5A.

FIG. 6A is a plan view showing an outlined configuration of a semiconductor device according to a fourth embodiment of the present invention.

FIG. 6B is a diagram showing an outlined configuration of the semiconductor device according to the fourth embodiment of the present invention and is a cross-sectional view taken along line E-E′ of FIG. 6A.

FIG. 6C is a diagram showing an outlined configuration of the semiconductor device according to the fourth embodiment of the present invention and is a cross-sectional view taken along line F-F′ of FIG. 6A.

FIG. 7A is a plan view showing an outlined configuration of a semiconductor device according to a fifth embodiment of the present invention.

FIG. 7B is a diagram showing an outlined configuration of the semiconductor device according to the fifth embodiment of the present invention and is a cross-sectional view taken along line G-G′ of FIG. 7A.

FIG. 7C is a diagram showing an outlined configuration of the semiconductor device according to the fifth embodiment of the present invention and is a cross-sectional view taken along line H-H′ of FIG. 7A.

### DESCRIPTION OF EXEMPLARY EMBODIMENTS

The present invention will be now described herein with reference to illustrative exemplary embodiments. Those skilled in the art will recognize that many alternative embodiments can be accomplished using the teachings of the present invention and that the invention is not limited to the exemplary embodiments illustrated for explanatory purposes.

Exemplary embodiments of the invention will be described in detail with reference to the drawings.

### First Exemplary Embodiment

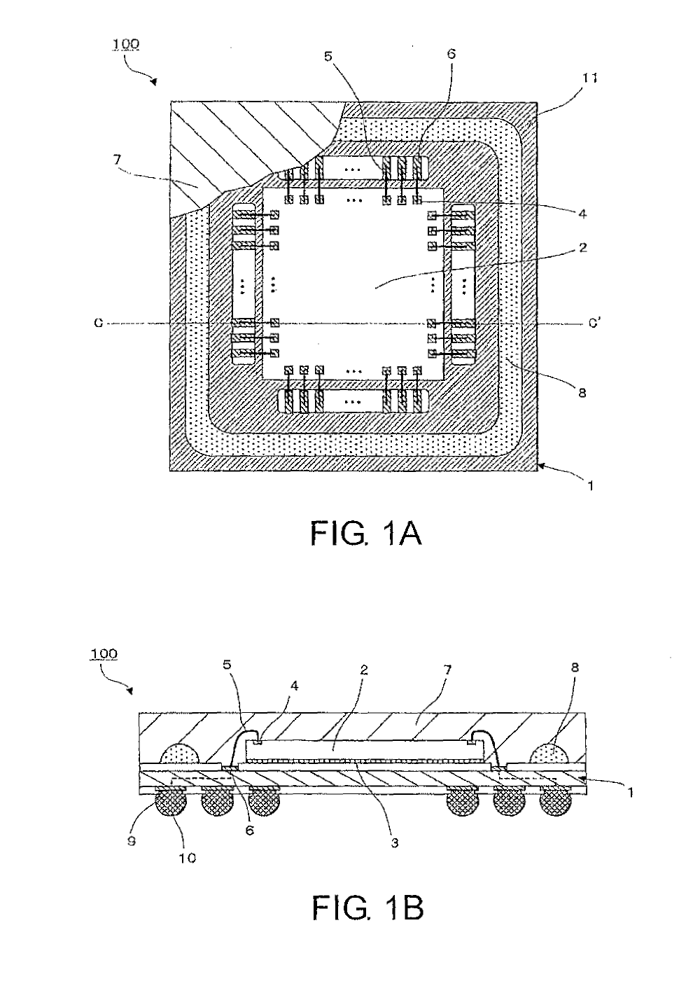

FIG. 1A is a plan view showing an outlined configuration of a semiconductor device 100 according to a first exemplary embodiment of the present invention. FIG. 1B is a diagram showing an outlined configuration of the semiconductor device 100 according to the first exemplary embodiment of the present invention. FIG. 1B is a cross-sectional view taken along line C-C′ of FIG. 1A.

As shown in FIG. 1, the semiconductor device 100 of the first exemplary embodiment includes a wiring board 1, a semiconductor chip 2 mounted on a first surface of the wiring board 1, and an adhesive member 3 interposed between the wiring board 1 and the semiconductor chip 2. For example, the wiring board 1 is formed of a glass epoxy substrate.

The semiconductor chip 2 includes electrode pads 4 arranged in a peripheral area thereof. The wiring board 1 has connection pads 6 formed thereon. The electrode pads 4 of the semiconductor chip 2 are electrically connected to the connection pads 6 of the wiring board 1 by wires 5. A sealing resin 7 is formed on the first surface of the wiring board 1 so that the semiconductor chip 2 and the wires 5 are covered with the sealing resin 7. A solder resist film 11 is formed on the first surface of the wiring board 1. Lands 9 are formed on a second surface of the wiring board 1. Solder balls 10 are mounted on the lands 9.

As shown in FIG. 1B, the semiconductor device 100 of the first exemplary embodiment has a low-elasticity resin 8 formed between the wiring board 1 and the sealing resin 7. The low-elasticity resin 8 is formed of a material having an elastic modulus lower than the elastic modulus of the sealing resin 7. For example, the low-elasticity resin 8 is formed of a silicone resin or an underfill. As shown in FIG. 1A, the low-elasticity resin 8 is roughly in the form of a frame located outside of a position at which the semiconductor chip 2 is mounted.

Thus, the low-elasticity resin 8, which has an elastic modulus lower than the elastic modulus of the sealing resin 7, is arranged between the wiring board 1 and the sealing resin 7. Therefore, the low-elasticity resin 8 serves as a cushioning material (or a buffer material) between the wiring board 1 and the sealing resin 7 to reduce influence from cure shrinkage of the sealing resin 7. Thus, a warp of the semiconductor device 100 can be reduced. Furthermore, a warp of the semiconductor device can readily be adjusted at a development stage. Thus, the development period can be shortened, and the development cost can be reduced.

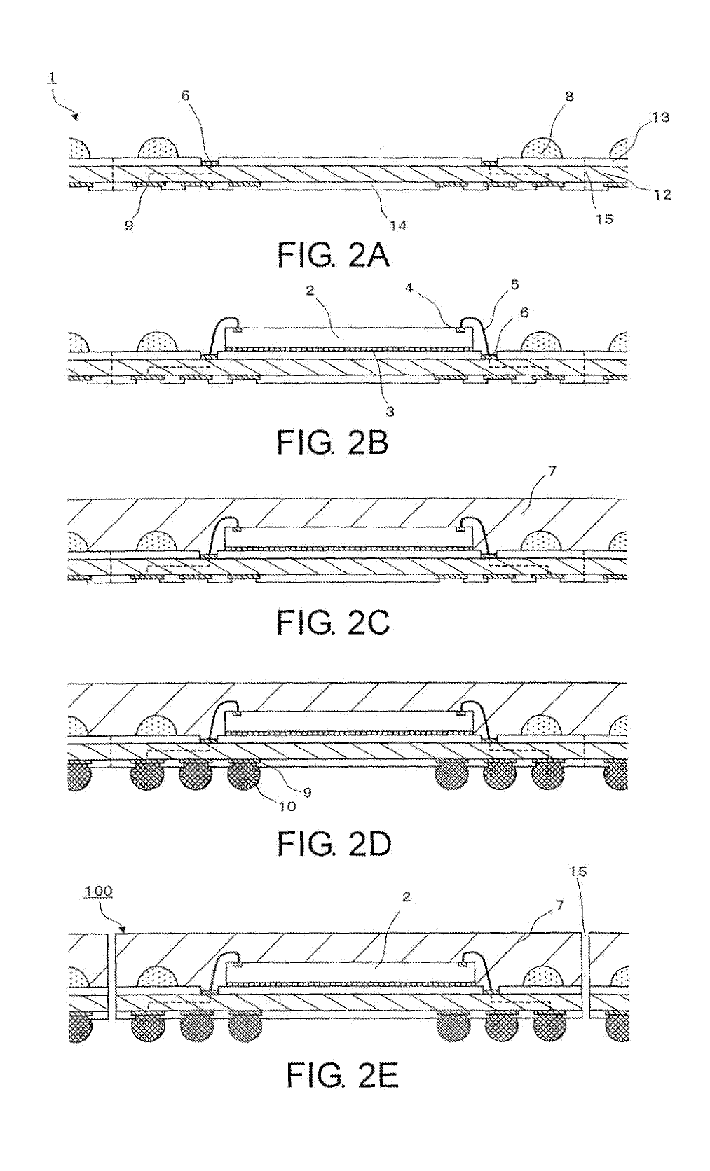

Now, a method of manufacturing a semiconductor device according to the first exemplary embodiment will be described with reference to FIGS. 2A to 2E as well as FIGS. 1A and 1B. FIGS. 2A to 2E are cross-sectional views showing a flow of assembling a semiconductor device 100 according to the first exemplary embodiment.

First, as shown in FIG. 2A, a wiring board 1 is prepared. The wiring board 1 is formed of an insulating substrate 12. The wiring board 1 has a first surface on which an insulator film 13 and connection pads 6 have been formed. The wiring board 1 has a second surface on which an insulator film 14 and lands 9 have been formed. Dicing lines 15 are formed in the wiring board 1.

Before a semiconductor chip 2 is mounted, a low-elasticity resin 8 is supplied by a dispenser of a coater (not shown) such that the low-elasticity resin 8 draws like a frame located outside of a position at which the semiconductor chip 2 is to be mounted on the wiring board 1. Then the low-elasticity resin 8 supplied onto the wiring board 1 is cured at a certain temperature and thus hardened.

Thus, the low-elasticity resin 8 is arranged roughly in the form of a frame at a peripheral portion of the wiring board 1. Therefore, the rigidity of the thin wiring board 1 can be enhanced. Accordingly, the handling ease of the thin wiring board 1 can be improved.

Subsequently, as shown in FIG. 2B, a semiconductor chip 2 having a rear face on which an adhesive member 3 has been formed is mounted on the wiring board 1. Then electrode pads 4 of the semiconductor chip 2 are electrically connected to the connection pads 6 of the wiring board 1 by wires 5.

For example, the wires 5 are made of Au or the like. Each of the wires 5 is melted so as to form a ball at its tip and connected to the corresponding electrode pad 4 of the semiconductor chip 2 with a wire bonding apparatus (not shown) by supersonic thermocompression bonding. Then the other end of the wire 5 is connected to the corresponding connection pad 6 by supersonic thermocompression bonding so that the wire 5 is curved into a certain loop shape.

Thereafter, as shown in FIG. 2C, a sealing resin 7 is formed on the first surface of the wiring board 1 by a batch molding process. For example, the sealing resin 7 is formed as follows: The wiring board 2 is clamped by a molding tool including an upper mold and a lower mold of a transfer molding apparatus (not shown). A thermosetting epoxy resin is injected from a gate into a cavity formed by the upper mold and the lower mold, filled in the cavity, and then heat-cured to form the sealing resin 7.

Next, as shown in FIG. 2D, solder balls 10 are mounted on lands 9 formed on the second surface of the wiring board 1. Thus, external terminals (bump electrodes) are formed. The ball mounting process uses a suction mechanism (not shown) having a plurality of suction holes formed therein so as to correspond to positions of the lands 9 of the wiring board 1. The solder balls 10 are held by the suction holes. A flux is transferred to the solder balls 10 being held. Then the solder balls 10 are collectively mounted on the lands 9 of the wiring board 1. After the solder balls 10 have been mounted, a reflow process is performed to form external terminals.

Then, as shown in FIG. 2E, the wiring board 1 with the external terminals formed thereon is cut along the dicing lines 15 and separated into individual boards. Upon the board dicing, the sealing resin 7 on the wiring board 1 is bonded to a dicing tape, so that the dicing tape supports the wiring board 1. The wiring board 1 is cut along the dicing lines 15 longitudinally and latitudinally by a dicing blade (not shown) to thus singulate the wiring board 1. After completion of the singulation, each semiconductor device is picked up from the dicing tape. Thus, a semiconductor device 100 as shown in FIG. 1 is obtained.

In this example, the low-elasticity resin 8 is supplied before the mounting of the semiconductor chip 2 in order to improve the handling ease of the thin wiring board 1. Nevertheless, the low-elasticity resin 8 may be supplied after the mounting of the semiconductor chip 2 or after the wire bonding.

Thus, in the first exemplary embodiment, the low-elasticity resin 8 having an elastic modulus lower than the elastic modulus of the sealing resin 7 is provided between the wiring board 1 and the sealing resin 7. Therefore, the low-elasticity resin 8 serves as a cushioning material between the sealing resin 7 and the wiring board 1. Therefore, a warp of the semiconductor device 100 can be reduced after the sealing.

Furthermore, when the sealing resin is formed by a transfer molding apparatus, a filler may be distributed differently between product areas near a gate and product areas near an air vent. Thus, the produced warp may vary depending upon product areas. However, according to the first exemplary embodiment, the low-elasticity resin 8 having an elastic modulus lower than the elastic modulus of the sealing resin 7 is provided between the wiring board 1 and the sealing resin 7 for each of the product areas. Therefore, variations between the product areas can be reduced.

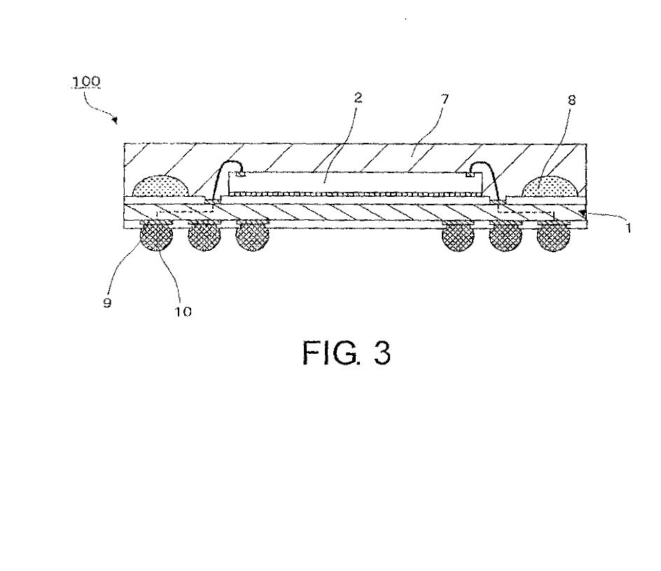

FIG. 3 is a cross-sectional view showing a variation of the semiconductor device 100 according to the first exemplary embodiment of the present invention.

As shown in FIG. 3, the width of the low-elasticity resin 8 may be changed so as to change contacting areas between the wiring board 1 and the sealing resin 7, thereby adjusting a warp of the semiconductor device 100. For example, when a large warp is caused, an area of the low-elasticity resin 8 may be further increased to reduce contacting areas between the wiring board 1 and the sealing resin 7. Thus, a warp can further be reduced.

### Second Exemplary Embodiment

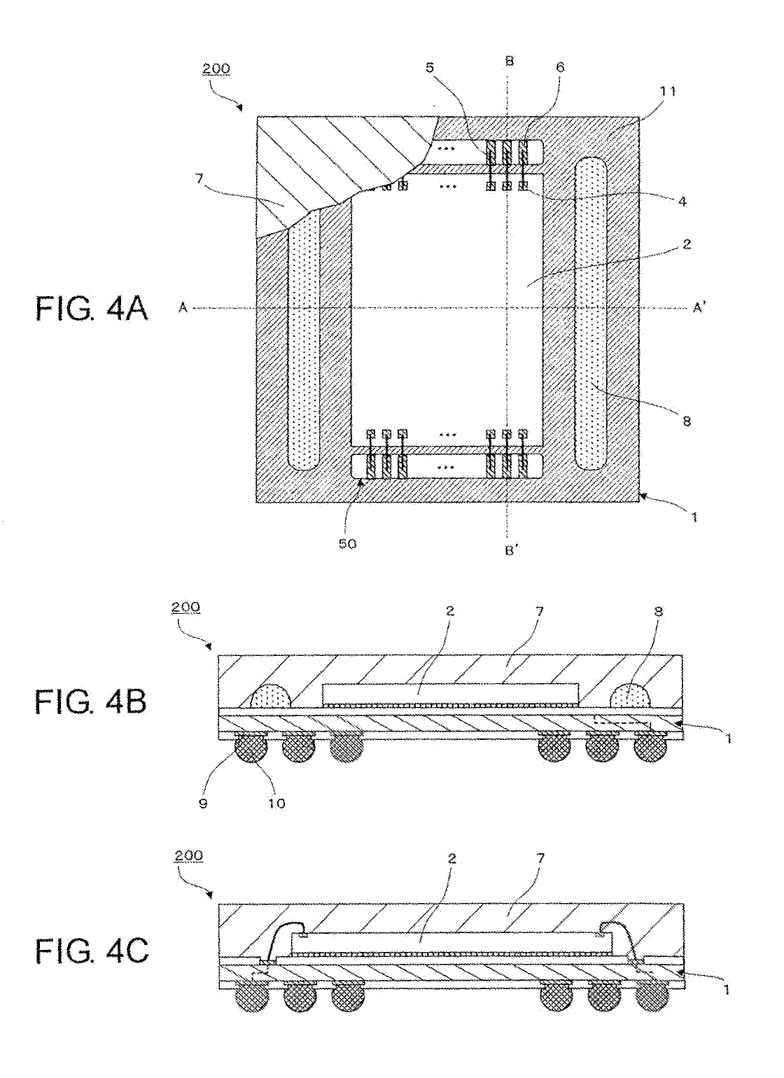

FIG. 4A is a plan view showing an outlined configuration of a semiconductor device 200 according to a second exemplary embodiment of the present invention. FIG. 4B is a diagram showing an outlined configuration of the semiconductor device 200 according to the second exemplary embodiment of the present invention. FIG. 4B is a cross-sectional view taken along line A-A′ of FIG. 4A. FIG. 4C is a diagram showing an outlined configuration of the semiconductor device 200 according to the second exemplary embodiment of the present invention. FIG. 4C is a cross-sectional view taken along line B-B′ of FIG. 4A.

For the sake of convenience, the same components as those of the semiconductor device 100 illustrated in FIG. 1 are denoted by the same reference numerals. In FIGS. 4A to 4C, the reference numeral 50 denotes opening portions.

In the second exemplary embodiment, a semiconductor chip 2 mounted on the wiring board 1 roughly has a rectangular shape. This example shows a case where an area between a longitudinal end of the semiconductor chip 2 and an end of the wiring board 1 differs from an area between a lateral end of the semiconductor chip 2 and an end of the wiring board 1. In this case, a contact area between the wiring board 1 and the sealing resin 7 is larger in the lateral direction, and thus a larger amount of the sealing resin 7 is arranged in the lateral direction. Since the sealing resin 7 is larger in the lateral direction than in the longitudinal direction, a warp of the semiconductor device 200 is caused. Therefore, low-elasticity resins 8 are provided only in the lateral direction, which has larger areas between ends of the semiconductor chip 2 and ends of the wiring board 1. Thus, a warp is adjusted in the lateral direction, thus reducing the entire warp of the semiconductor device 200.

Furthermore, since the low-elasticity resins 8 are provided only in areas in which no connection pads 6 have been formed, a risk that the connection pads 6 are covered with the low-elasticity resins 8 can be reduced.

### Third Exemplary Embodiment

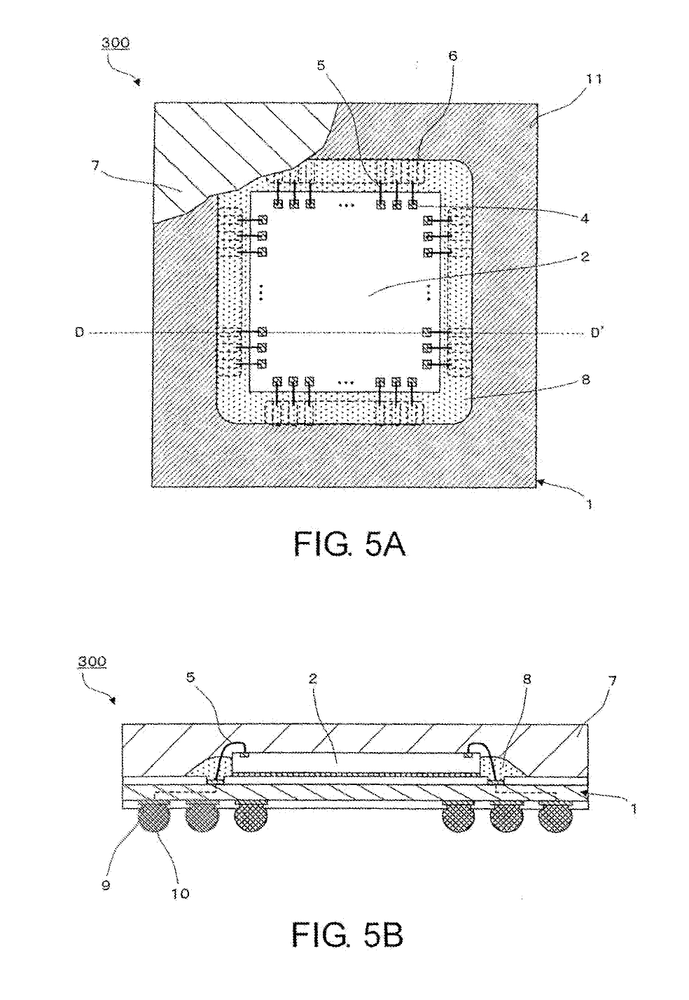

FIG. 5A is a plan view showing an outlined configuration of a semiconductor device 300 according to a third exemplary embodiment of the present invention. FIG. 5B is a diagram showing an outlined configuration of the semiconductor device 300 according to the third exemplary embodiment of the present invention. FIG. 5B is a cross-sectional view taken along line D-D′ of FIG. 5A.

For the sake of convenience, the same components as those of the semiconductor device 100 illustrated in FIG. 1 are denoted by the same reference numerals.

The third exemplary embodiment differs from the first exemplary embodiment in that side surfaces of the semiconductor chip 2 are also covered with a low-elasticity resin 8. In this case, a low-elasticity resin 8 is applied to and formed in a peripheral portion of the semiconductor chip 2 after wire bonding.

The same advantageous effects as in the first embodiment can be obtained in the third embodiment. Additionally, since the side surfaces of the semiconductor chip 2 are covered with the low-elasticity resin 8, voids can be prevented from being generated on the side surfaces of the semiconductor chip 2 upon sealing. Furthermore, since the wires 5 are covered with the low-elasticity resin 8, those wires can be prevented from being drifted or short-circuited.

If the low-elasticity resin 8 is located above the semiconductor chip 2, the sealing resin 7 should be provided on the low-elasticity resin 8 because it is difficult to produce a mark on the low-elasticity resin 8. As a result, the thickness of the sealing resin 7 above the semiconductor chip 2 needs to be increased, which inhibits the semiconductor device 300 from being reduced in thickness. Accordingly, it is preferable not to provide the low-elasticity resin 8 above the semiconductor chip 2.

### Fourth Exemplary Embodiment

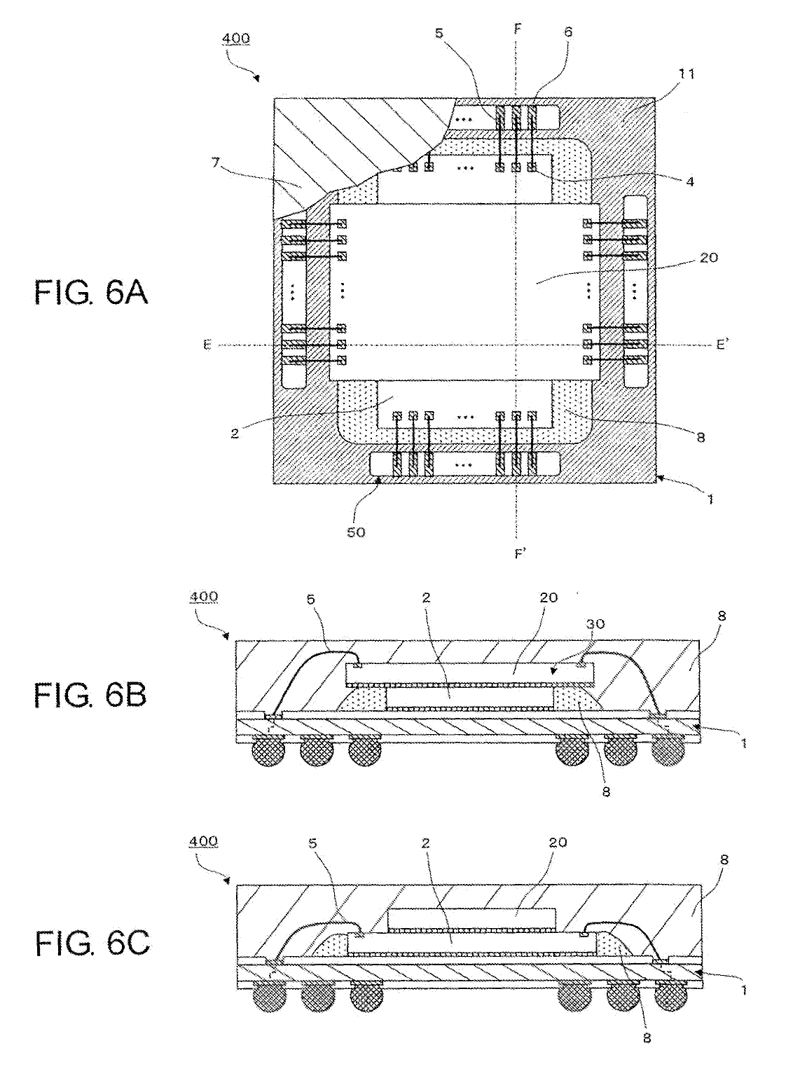

FIG. 6A is a plan view showing an outlined configuration of a semiconductor device 400 according to a fourth exemplary embodiment of the present invention. FIG. 6B is a diagram showing an outlined configuration of the semiconductor device 400 according to the fourth exemplary embodiment of the present invention. FIG. 6B is a cross-sectional view taken along line E-E′ of FIG. 6A. FIG. 6C is a diagram showing an outlined configuration of the semiconductor device 400 according to the fourth exemplary embodiment of the present invention. FIG. 6C is a cross-sectional view taken along line F-F′ of FIG. 6A.

For the sake of convenience, the same components as those of the semiconductor device 100 illustrated in FIG. 1 are denoted by the same reference numerals.

In the fourth exemplary embodiment, a first semiconductor chip 2 is mounted on the wiring board 1, and a second semiconductor chip 20 is stacked on the first semiconductor chip 2. The second semiconductor chip 20 is stacked so as to overhang from the first semiconductor chip 2. A low-elasticity resin 8 is provided around the first semiconductor chip 2 so that the low-elasticity resin 8 is also located below the overhanging portions 30 of the second semiconductor chip 20.

The same advantageous effects as in the third embodiment can be obtained in the fourth embodiment. Additionally, the low-elasticity resin 8 can support the overhanging portions 30 of the second semiconductor chip 20. Thus, chip cracks are prevented from being generated upon wire bonding of the second semiconductor chip 20. Therefore, satisfactory wire connections can be established.

### Fifth Exemplary Embodiment

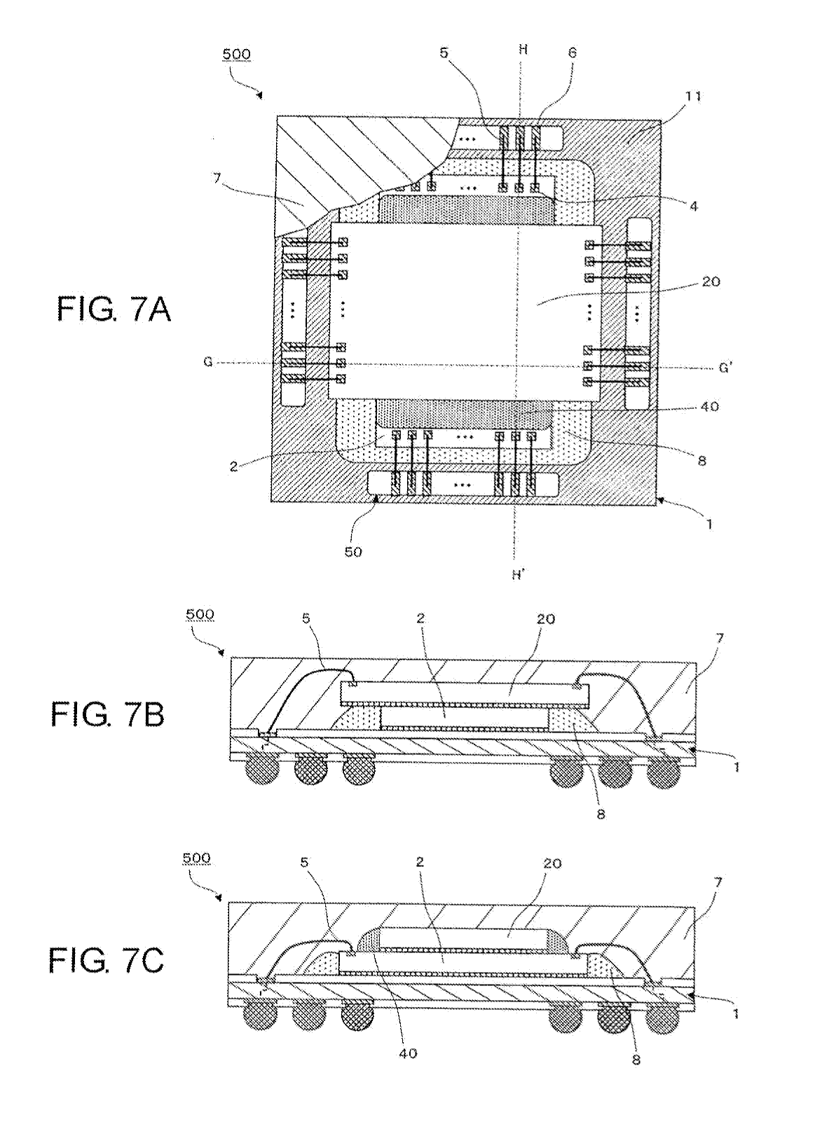

FIG. 7A is a plan view showing an outlined configuration of a semiconductor device 500 according to a fifth exemplary embodiment of the present invention. FIG. 7B is a diagram showing an outlined configuration of the semiconductor device 500 according to the fifth exemplary embodiment of the present invention. FIG. 7B is a cross-sectional view taken along line G-G′ of FIG. 7A. FIG. 7C is a diagram showing an outlined configuration of the semiconductor device 500 according to the fifth exemplary embodiment of the present invention. FIG. 7C is a cross-sectional view taken along line H-H′ of FIG. 7A.

For the sake of convenience, the same components as those of the semiconductor device 400 illustrated in FIG. 6 are denoted by the same reference numerals.

The fifth exemplary embodiment has the same configuration as the fourth embodiment except that a low-elasticity resin 40 is also arranged on the first semiconductor chip 2.

When the first semiconductor chip 2 and the second semiconductor chip 20 are stacked crosswise, the thickness of the resin located above the chips is larger in the direction of H-H′ than in the direction of G-G′. Therefore, a hollowed warp is more likely to be generated in the direction of H-H′, in which the sealing resin 7 is thicker, than in the direction of G-G′.

The same advantageous effects as in the fourth exemplary embodiment can be obtained in the fifth exemplary embodiment. Additionally, a hollowed warp can be prevented in the direction of H-H′ as the low-elasticity resin 40 is disposed on the first semiconductor chip 2. Therefore, the balance of the warp can be improved in the XY-directions.

In the fifth exemplary embodiment, the low-elasticity resin 40 is arranged so that the low-elasticity resin 40 does not cover the electrode pads 4 of the first semiconductor chip 2. Nevertheless, when the low-elasticity resin 40 is formed on the first semiconductor chip 2 after wires have been connected to the first semiconductor chip 2, the low-elasticity resin 40 may cover the electrode pads 4 of the first semiconductor chip 2.

According to the present invention, a warp of a semiconductor device can be reduced at a lower cost with a shorter development period without any obstruction to thickness reduction.

The invention made by the inventors has been described based upon some embodiments. However, the present invention is not limited to the aforementioned embodiments. It would be apparent to those skilled in the art that many modifications and variations may be made therein without departing from the spirit and scope of the present invention.

In the above exemplary embodiments, the low-elasticity resin 8 is formed locally on the wiring board 1. Nevertheless, the low-elasticity resin 8 may be formed on the entire surface of the wiring board 1 except a chip mounting area.

Furthermore, in the above exemplary embodiments, the wiring board is made of a glass epoxy substrate. Nevertheless, the present invention is applicable to a flexible wiring board made of a polyimide substrate or the like.

A part of or the entirety of the embodiment mode described above can also be described as follows. The following notes, however, do not limit this invention in any way.

[Note 1] A semiconductor device, comprising:

a wiring board;

a first semiconductor chip mounted on a surface of the wiring board;

a second semiconductor chip stacked on the first semiconductor chip to form an overhanging portion that overhangs from the first semiconductor chip;

a sealing resin arranged on the surface of the wiring board to cover the first semiconductor chip and the second semiconductor chip; and

a low-elasticity resin arranged between the wiring board and the sealing resin;

wherein the low-elasticity resin has an elastic modulus lower than an elastic modulus of the sealing resin, and

the overhanging portion of the second semiconductor chip is located above the low-elasticity resin.

[Note 2] The semiconductor device as recited in note 1, further comprising:

an additional low-elasticity resin arranged on the first semiconductor chip between the wiring board and the sealing resin;

wherein the additional low-elasticity resin has an elastic modulus lower than the elastic modulus of the sealing resin.

[Note 3] The semiconductor device as recited in note 1, wherein the low-elasticity resin serves as a cushioning material between the wiring board and the sealing resin to reduce a warp of the semiconductor device.

[Note 4] A semiconductor device comprising:

a wiring board;

a first semiconductor chip mounted on a surface of the wiring board;

a resin portion arranged on the wiring board so as to extend at least along two opposing sides of the first semiconductor chip;

a second semiconductor chip stacked on the first semiconductor chip so that two opposing sides of the second semiconductor chip are located above the resin portion; and

a sealing resin for covering the first semiconductor chip, the second semiconductor chip, and the resin portion.

[Note 5] The semiconductor device as recited in note 4, wherein the resin portion has an elastic modulus lower than an elastic modulus of the sealing resin.

[Note 6] A method of manufacturing a semiconductor device, comprising:

preparing a wiring board;

forming a low-elasticity resin outside of a chip mounting area on a surface of the wiring board;

mounting a semiconductor chip on the chip mounting area; and

forming a sealing resin on the surface of the wiring board to cover the semiconductor chip and the low-elasticity resin,

wherein the low-elasticity resin has an elastic modulus lower than an elastic modulus of the sealing resin.

[Note 7] The method as recited in note 6, wherein the forming of the low-elasticity resin includes:

supplying the low-elasticity resin to an outside of the chip mounting area, and

curing the low-elasticity resin supplied onto the wiring board at a predetermined temperature to harden the low-elasticity resin.

[Note 8] The method as recited in note 6, wherein the low-elasticity resin serves as a cushioning material between the wiring board and the sealing resin to reduce a warp of the semiconductor device.

[Note 9] The method as recited in note 6, wherein the forming of the low-elasticity resin includes arranging the low-elasticity resin in a form of a frame located outside of the chip mounting area.

[Note 10] The method as recited in note 6, further comprising:

varying a width of the low-elasticity resin to change a contact area between the wiring board and the sealing resin, thereby adjusting the warp of the semiconductor device.

[Note 11] The method as recited in note 6, wherein the forming of the low-elasticity resin includes using a silicone resin or an underfill for the low-elasticity resin.

What is claimed is:

1. A semiconductor device, comprising:
a wiring board;
a semiconductor chip mounted over a surface of the wiring board;
a sealing resin provided over the surface of the wiring board to cover the semiconductor chip; and
a low-elasticity resin provided between the wiring board and the sealing resin, the low-elasticity resin being arranged outside of an area on which the semiconductor chip is mounted,
wherein the low-elasticity resin has an elastic modulus lower than an elastic modulus of the sealing resin.

2. The semiconductor device as recited in claim 1, wherein the low-elasticity resin serves as a cushioning material between the wiring board and the sealing resin to reduce a warp of the semiconductor device.

3. The semiconductor device as recited in claim 1, wherein the low-elasticity resin is provided in a form of a frame located outside of the semiconductor chip.

4. The semiconductor device as recited in claim 1, wherein the warp of the semiconductor device is adjusted by varying a width of the low-elasticity resin.

5. The semiconductor device as recited in claim 1, wherein the semiconductor chip has a substantially rectangular shape,
a first area between an edge of the semiconductor chip and an edge of the wiring board in a lateral direction is configured to be wider than a second area between an edge of the semiconductor chip and an edge of the wiring board in a longitudinal direction, and
the low-elasticity resin is arranged only in the first area along the longitudinal direction.

6. The semiconductor device as recited in claim 1, wherein the low-elasticity resin is not arranged on an upper surface of the semiconductor chip but is arranged to cover side surfaces of the semiconductor chip.

7. The semiconductor device as recited in claim 1, wherein the low-elasticity resin comprises a silicone resin or an underfill.

8. A semiconductor device comprising:
a substrate including an upper surface thereof;
a semiconductor chip including a first surface defined by first and second edges opposite to each other and by third and fourth edges opposite to each other and a plurality of electrode pads formed on the first surface along each of the first and second edges, and the semiconductor chip being mounted over the upper surface of the substrate;
a plurality of connection pads provided on the upper surface of the substrate, the connection pads being arranged along each of the first and second edges of the semiconductor chip, and the connection pads being electrically coupled to the electrode pads of the semiconductor chip, respectively;
first and second low-elasticity resins provided over the upper surface of the substrate, the first low-elasticity resin being arranged along the third edge of the semiconductor chip, and the second low-elasticity resin being arranged along the fourth edge of the semiconductor chip; and
a sealing resin provided over the upper surface of the substrate to cover the semiconductor chip and the first and second low-elasticity resins,
wherein an elastic modulus of the first and second low-elasticity resin is smaller than that of the sealing resin.

9. The semiconductor device as recited in claim 8, wherein the first and second low-elasticity resins are provided over the upper surface of the substrate so that the first and second low-elasticity resins are apart from the semiconductor chip.

10. The semiconductor device as recited in claim 8, wherein the first and second low-elasticity resins are provided over the upper surface of the substrate so that each of the first and second low-elasticity resins is in contact with the semiconductor chip.

11. The semiconductor device as recited in claim 8, further comprising:
third and fourth low-elasticity resins provided over the upper surface of the substrate, the third low elasticity resin being arranged along the first edge of the semiconductor chip, the fourth low-elasticity resin being arranged along the second edge of the semiconductor chip, and each of the first and second low-elasticity resins being coupled to the third and fourth low-elasticity resins.

12. The semiconductor device as recited in claim 10, further comprising:
a second semiconductor chip including a second surface defined by fifth and sixth edges opposite to each other and by seventh and eighth edges opposite to each other and a plurality of second electrode pads formed on the second surface along each of the fifth and sixth edges, and the second semiconductor chip being stacked over the semiconductor chip so that the fifth and sixth edges are in parallel to the third and fourth edges of the semiconductor chip; and
a plurality of second connection pads formed on the upper surface of the substrate, the second connection pads being arranged along each of the fifth and sixth edges of the second semiconductor chip, and the second connection pads being electrically coupled to the second electrode pads of the second semiconductor chip.

13. A semiconductor device comprising:
a substrate;
a semiconductor chip including a plurality of electrode pads thereon, and the first semiconductor chip being mounted over an upper surface of the substrate;
a plurality of connection pads formed on the upper surface of the substrate so as to arrange outside of the semiconductor chip, and the connection pads being coupled to the electrode pads of the semiconductor chip;
a low-elasticity resin provided over the upper surface of the substrate so as to surround the semiconductor chip in plan view; and
a sealing resin provided over the first surface of the substrate to cover the semiconductor chip and the low-elasticity resin,
wherein the low-elasticity resin has an elastic modulus lower than an elastic modulus of the sealing resin.

14. The semiconductor device as recited in claim 13, wherein the low-elasticity resin is provided over the upper surface of the substrate so that the low-elasticity resin is apart from the semiconductor chip.

15. The semiconductor device as recited in claim 13, wherein the low-elasticity resin is provided over the upper surface of the substrate so that the low-elasticity resin is in contact with the semiconductor chip.

16. The semiconductor device as recited in claim 13, further comprising:
a second semiconductor chip stacked over the semiconductor chip so that the electrode pads of the semiconductor chip expose from the second semiconductor chip.

17. The semiconductor device as recited in claim 13, wherein the low-elasticity resin is provided over the upper surface of the substrate so as to arrange outside of the connection pads.

18. The semiconductor device as recited in claim 16, wherein the semiconductor chip includes an uncovered portion that is uncovered with the second semiconductor chip, and the semiconductor device further comprises:
a second low-elasticity resin provided on the uncovered portion of the semiconductor chip, the second low-elasticity resin being between the semiconductor chip and the sealing resin.

19. The semiconductor device as recited in claim 13, wherein a first width of the low-elasticity resin in a first direction is larger than a second width of the low-elasticity resin in a second direction that is perpendicular to the first direction.

20. The semiconductor device as recited in claim 13, wherein the low-elasticity resin comprises a silicone resin ore underfill.
